(19) United States
(12) Patent Application Publication
(10) Pub. No.: US 2005/0210348 A1
(43) Pub. Date: Sep. 22, 2005

(54) Microcomputer and method of testing same

(75) Inventor: Kazufumi Totsuka, Kawasaki (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION

(21) Appl. No.: 11/079,083

(22) Filed: Mar. 15, 2005

(30) Foreign Application Priority Data
Mar. 16, 2004 (JP) 2004-073875

(51) Int. Cl. G01R 31/28; G06F 11/00

(52) U.S. Cl. 714/724

(57) ABSTRACT

A microcomputer includes a memory such as a flash memory; a logical circuit such as a CPU; a test ROM storing a test program for testing at least the logical circuit; and recording means capable of storing, as a flag, the result of testing at least one of the memory and logical circuit. The memory and the logical circuit are tested simultaneously to shorten test time. The test-result flag is checked upon being stored. When the flag indicates failure of the logical circuit, testing of the memory is aborted, and vice versa.

### BACKGROUND OF THE INVENTION

1. Field of the Invention

This invention relates to a microcomputer having a memory such as a flash memory and a logical circuit such as a CPU for executing logical operations. More particularly, the invention relates to a microcomputer that is capable of undergoing a test of the memory and a test of the logical circuit in a short period of time.

2. Description of the Related Art

When a microcomputer incorporating a memory such as a flash memory, which is an electrically rewritable non-volatile memory, is tested, either the memory or the logic such as the CPU that executes logical operations is tested first. Then, when the item tested has been found to be acceptable, the other item is tested. Whichever of the memory or logic is tested first is not uniquely decided. However, when the failure rates of the memory and logic are compared, it is found that the failure rate is higher for the memory, which has a large number of constituent elements. In general, therefore, the memory is tested first and, if the memory does not fail the test, then the logical circuit is tested. Consequently, total test time is the sum of memory test time and logical circuit test time and a problem which arises is that test time is lengthy. Further, the time required to test the memory is much longer than that required to test the logical circuit. This means that if a defect is found with testing of the logical circuit after the memory has been tested, then the test of the memory performed first represents time wasted.

In an effort to solve the problem of prolonged test time, the specification of Japanese Patent Application Kokai Publication No. P2003-346499A proposes testing the logical circuit utilizing idle time available when the memory is being tested. According to the art disclosed in this reference, as illustrated schematically in FIG. 5, a memory (flash memory) 110 and logical circuit (CPU) 120 of a microcomputer 100B are connected to a test apparatus 200 via a switching circuit 190, the flash memory 110 and CPU 120 are switched and connected selectively to the test apparatus 200 by the switching circuit 190, a memory test pattern is input to the flash memory in a pattern input interval, the memory test pattern is subsequently latched internally and is written to the memory in a program interval that follows the pattern input interval. The program interval is so-called idle time during which each circuit of the microcomputer is idle. Accordingly, by inputting a logic test pattern to the logical circuit and testing the logical circuit in the program interval, total test time is shortened.

According to the prior art set forth in the above-mentioned patent reference, a memory test pattern and a logic test pattern are input from the test apparatus 200 to the microcomputer 100B while being switched with the passage of time and, hence, the switching circuit 190 is essential for changing over the input. Since switching circuits 190 are required in a number equivalent to the number of pins necessary to input the test pattern, a problem which arises is that the microcomputer has an architecture of large size. In particular, since the testing of the memory requires a prolonged period of time, as mentioned above, it is preferred that a large number of microcomputers be connected to a single test apparatus. However, since the number of pins with which a test apparatus is provided is limited, the number of pins of the microcomputer connected to the test apparatus must be limited to a very small number. Accordingly, if the terminals required for testing of the flash memory are connected to the test apparatus, the pins of the test apparatus that have been assigned to one microcomputer are used up solely by the pins of the flash memory. As a result, many of the large number of pins with which the microcomputer is provided are not connected to the test apparatus and it is difficult to test satisfactorily the logical circuit in the microcomputer performed using these numerous pins. If testing of logic is made possible, the number of pins that connect the test apparatus to a single microcomputer will increase and the number of microcomputers tested in parallel will diminish, resulting in a decline in efficiency.

Further, according to the prior art described above, the memory and logical circuit are tested in a continuous series of steps. Consequently, even if a defect is found in the memory or logical circuit in the testing thereof, the series of tests continues and, as a result, test time is wasted.

### SUMMARY OF THE INVENTION

Accordingly, an object of the present invention is to provide a microcomputer and a method of testing the same in which a large number of switching circuits is made unnecessary to thereby reduce the size of the circuitry, and time wasted in testing is eliminated.

According to a first aspect of the present invention, the foregoing object is attained by providing a microcomputer comprising: a memory such as a flash memory; a logical circuit such as a CPU; a test ROM storing a test program for testing at least the logical circuit; and a recording device capable of storing, as a flag, a result of testing at least one of the memory and logical circuit. The microcomputer may further comprise means for checking the flag, which has been stored in the recording device, after the end of testing of at least one of the memory and logical circuit. The microcomputer may further comprise means for aborting a continuing test based upon result of checking the flag.

Further, according to the present invention, the foregoing object is attained by providing a method of testing a microcomputer having a memory such as a flash memory and a logical circuit such as a CPU, the method comprising the steps of: testing the memory and, at the same time, testing the logical circuit based upon a test program that has been stored in a test ROM incorporated in the microcomputer; storing a flag, which indicates a result of testing one of the memory and logical circuit, in the recording device; and aborting testing of the other of the memory and logical circuit when test failure is confirmed based upon the flag.

For example, a flag indicating result of testing the logical circuit is stored in the recording device and the testing of the memory is aborted when it is confirmed based upon the flag that the logical circuit is defective. Aborting of the memory test is performed by control exercised by a control macro of the memory. Alternatively, aborting of the memory test is performed by control exercised by the logical circuit.

In accordance with the present invention, the memory and the logical circuit are tested simultaneously, thereby making it possible to shorten test time. In addition, a large number of switching circuits is made unnecessary to thereby achieve a reduction in size. Further, the number of pins to be connected to a test apparatus can be reduced by conducting a test based upon the test ROM within the microcomputer. As a result, the number of microcomputers connectable to a single test apparatus can be increased and testing efficiency can be enhanced. Furthermore, the flag indicating the result of one test can be stored and checked. When the result of the test is found to be a defect, the other test is aborted. This eliminates wasted test time and shortens overall test time. Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

FIG. 1 is a block diagram illustrating a microcomputer according a first embodiment of the present invention;

FIG. 2 is a flowchart for describing a test operation according to the first embodiment;

FIG. 3 is a block diagram illustrating a microcomputer according a second embodiment of the present invention;

FIG. 4 is a flowchart for describing a test operation according to the second embodiment; and

FIG. 5 is a conceptual block diagram for describing an example of the prior art.

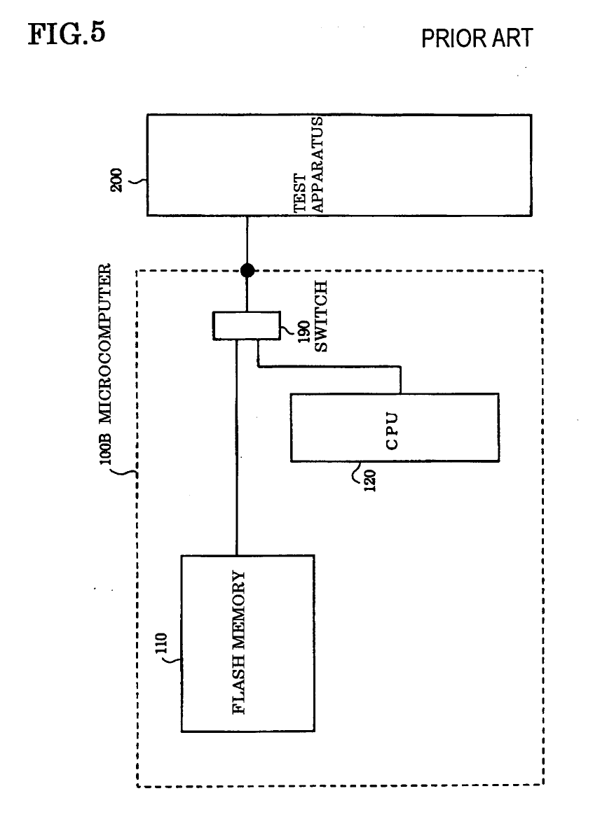

### DESCRIPTION OF THE PREFERRED EMBODIMENTS

Preferred embodiments of the present invention will now be described in detail with reference to the drawings.

### First Embodiment

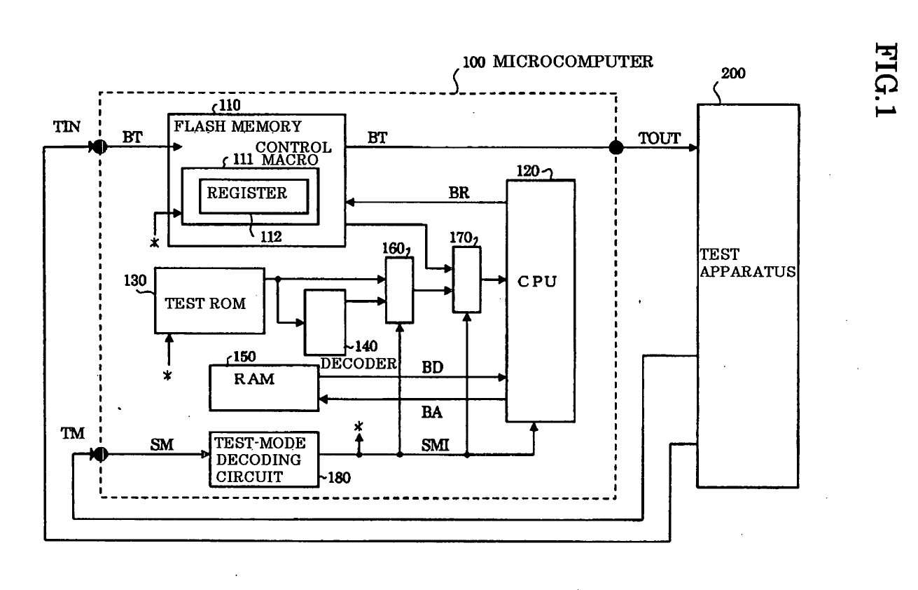

A first embodiment of the invention will be described with reference to FIG. 1, which is a block diagram illustrating the principal components of a microcomputer 100 having an internal flash memory 110 in accordance with the present invention.

As shown in FIG. 1, the microcomputer 100 includes the flash memory 110, which has a control macro 111 equipped with an internal register 112, and a CPU 120 for controlling the control macro 111 of the flash memory 110 to thereby execute prescribed operations beginning with writing and reading of data to and from the flash memory 110. The flash memory 110 and CPU 120 constitute a memory and a logical circuit, respectively, to be tested in accordance with the present invention. A test input terminal TIN and a test output terminal TOUT connected to an external test apparatus 200 have been connected to the flash memory 110 by a special-purpose test bus BT. A test pattern from the test apparatus 200 that has entered from the test input terminal TIN is written to the flash memory 110 by control exercised by the control macro 111, and the written test pattern is read out to the test apparatus 200 from the test output terminal TOUT. The test apparatus 200 conducts a test of the flash memory 110 based upon the test pattern that has been read out. The CPU 120, on the other hand, is connected to the flash memory 110 by a register setting bus BR and is capable of controlling the internal register 112 of the control macro 111.

The microcomputer 100 further includes a test ROM 130 in which a test program for testing the CPU 120 has been stored in the form of compressed code; and a test-program decoding circuit 140 for decoding the stored test program. After it has been decompressed or decoded, the test program is fetched by the CPU 120 which, based upon the test program, is capable of testing itself based upon the test program. Further, the microcomputer 100 is equipped with a RAM 150 that is accessible via an address bus BA and data bus BD. The test program that has been stored in the test ROM 130 can be expanded in the RAM 150 or a test-result flag that is output from the CPU 120 can be stored in the RAM 150.

The microcomputer 100 further includes a first selector 160 for selecting information from the test ROM 130 and information from the test-program decoding circuit 140, and a second selector 170 for selecting the output of the first selector 160 and information from the flash memory 110. Whatever is selected by the second selector 170 can be loaded into the CPU 120. The microcomputer 100 further includes a test-mode decoding circuit 180 for decoding a test mode signal SM, which enters from a test mode terminal TM, thereby obtaining an internal test mode signal SMI. The control macro 111 of the flash memory 110, the CPU 120, the test ROM 130 and the first and second selectors 160, 170, respectively, are controlled or changed over by the internal test mode signal SMI.

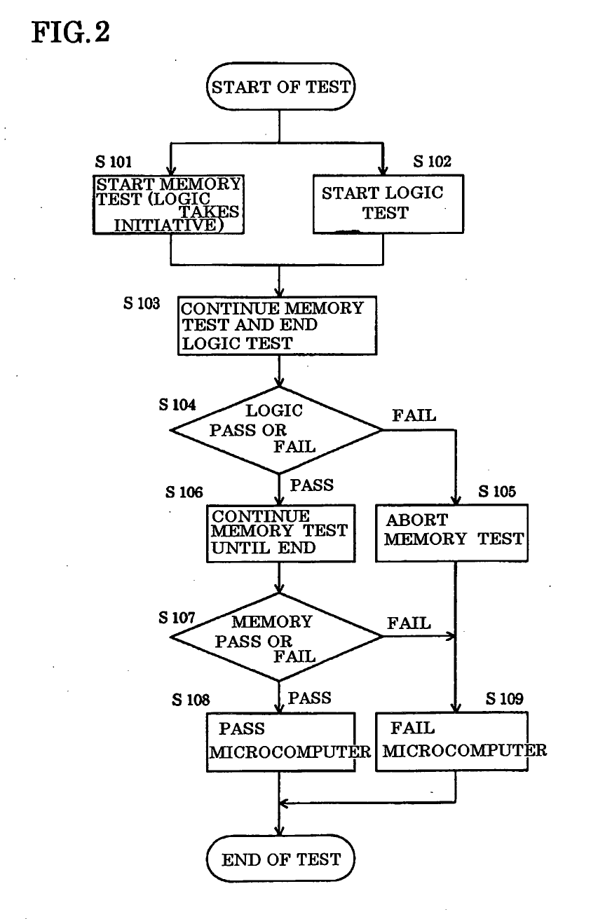

The operation for testing the microcomputer of the first embodiment set forth above will be described with reference to the flowchart of FIG. 2. When the test mode signal SM is input to the test mode terminal TM, the test-mode decoding circuit 180 generates the internal test mode signal SMI that conforms to the test mode, outputs the internal test mode signal SMI to the flash memory 110, CPU 120 and test ROM 130 and, at the same time, outputs the internal test mode signal SMI to the first and second selectors 160, 170, respectively. The internal test mode signal SMI is received within the flash memory 110 and a test pattern enters from the test apparatus 200 via the test input terminal TIN. The test pattern is written to the flash memory 110 based upon the test control program included in the internal test mode signal SMI in control macro 111. Further, the control macro 111 reads out the written test pattern and outputs the pattern to the external test apparatus 200 from the test output terminal TOUT. In response, the testing of the flash memory 110 starts (S101).

At the same time that testing of the flash memory 110 starts, the CPU 120 starts a testing operation in response to the internal test mode signal SMI. At this time assume that the first selector 160 selects the output of the test-program decoding circuit 140 and that the second selector 170 selects the output of the first selector 160 in response to the internal test mode signal SMI. The test-program decoding circuit 140 decodes the test program that has been stored in the test ROM 130, and the CPU 120 fetches the decoded test program and starts a test based upon an operation that is in accordance with the test program. Since the compressed test program stored in the test ROM 130 has been decompressed and decoded, a broad range of tests can be conducted by the CPU 120 even in a case where the test ROM 130 is of limited capacity. Further, in a case where the test program has been stored in the test ROM 130 without being compressed, the CPU 120 selects the test program of the test ROM 130 directly by the first selector 160 and expands the test program in the RAM 150. By then fetching this program, the CPU 120 can conduct a broad range of tests in a similar manner (S102).

In the present test, testing of the CPU 120 ends first even though testing of the flash memory 110 continues (S103). Pass (conforming article) or fail (defective article), which is the result of testing the CPU 120, is stored in the RAM 150 as a flag. Alternatively, the flags are sent from the CPU 120 to the flash memory 110 and are stored in the vacant register 112 within the control macro 111. Even during the course of testing the flash memory 110 that has not yet undergone a test, the control macro 111 constantly monitors the flag that has been stored in the internal register 112 or monitors the flag, which has been stored in the RAM 150, through the CPU 120 (S104). If fail has been confirmed by the flag, then the control macro 111 immediately aborts the testing of the flash memory 110 (S105) and decides that the microcomputer 100 is defective (S109). When testing of the CPU 120 is completed and a pass result is determined for the CPU 120 in the course of testing the flash memory 110, the testing of the flash memory 110 is continued until the memory test is completed (S106). Following the end of the test of the flash memory 110, it is determined from the result of this test whether the flash memory 110 has passed or failed (S107) and the pass or fail flag is stored in the internal register 112 or RAM 150. The CPU 120 thenceforth checks the flag that has been stored in the internal register 112 or RAM 150, decides that the microcomputer 100 is a conforming article in case of pass (S108) and decides that it is defective in case of fail (S109).

By adopting this arrangement, testing of the flash memory 110 serving as the memory and testing of the CPU 120 serving as a logical circuit can be conducted simultaneously. In the testing of the flash memory 110, test time is longer than that for testing the CPU 120 because all of the memory cells are tested by repeating the test for each individual memory cell. Consequently, total test time for the present test can be held to the test time of the flash memory 110, which has the longer test time, and hence it is possible to shorten test time. In addition, it goes without saying that wasted test time can be eliminated.

Accordingly, with the microcomputer 100 of the first embodiment, it is unnecessary to provide switching circuits for changing over the externally applied memory test pattern and logic test pattern as time passes, as is required in the above-mentioned patent reference. This makes it possible to simplify the architecture of the microcomputer and to reduce its size. Further, the number of pins to be connected to the test apparatus can be reduced by conducting the test based upon the test ROM within the microcomputer. As a result, it is unnecessary to increase the number of pins required for a single test apparatus, the number of microcomputers capable of being connected to the test apparatus and tested in parallel can be increased and therefore it is possible raise testing efficiency.

### Second Embodiment

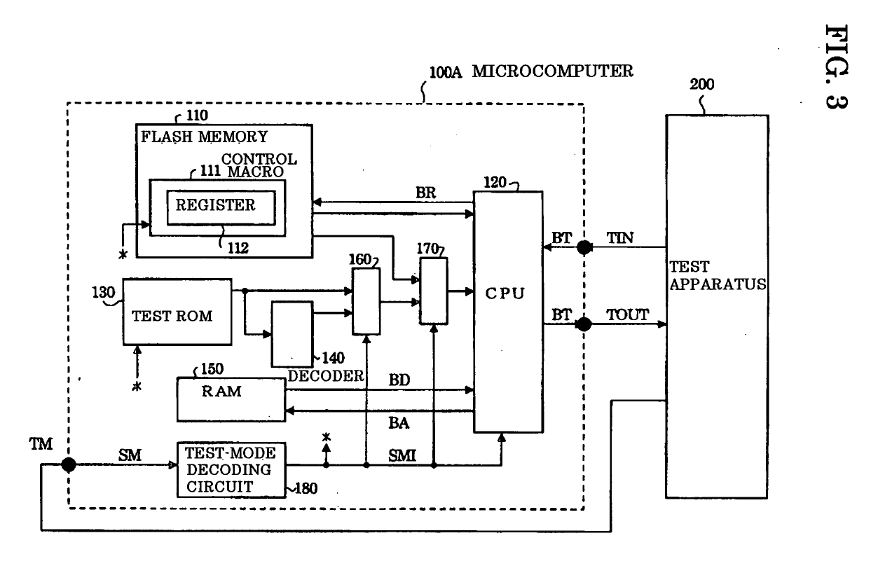

FIG. 3 is a block diagram of a microcomputer 100A according to a second embodiment, in which components identical with those of the first embodiment are designated by like reference characters. As shown in FIG. 3, the microcomputer 100A includes a flash memory 110, which serves as the memory and has a control macro 111 equipped with an internal register 112, and a CPU 120 serving as the logical circuit for controlling the control macro 111 of the flash memory 110 to thereby execute prescribed operations beginning with writing and reading of data to and from the flash memory 110. In the second embodiment, the test input terminal TIN and test output terminal TOUT connected to the external test apparatus have been connected to the CPU 120 by the special-purpose test bus BT. Thus it is possible to input and output a test signal between the CPU 120 and the test apparatus 200. Further, the CPU 120 is connected to the flash memory 110 by the register setting bus BR, which is bi-directional. Thus it is possible to control the control macro 111 of the flash memory 110 and to read out information that has been stored in the internal register 112. On the other hand, the second embodiment is such that the flash memory 110 is not connected directly to the test apparatus 200.

In a manner similar to that of the first embodiment described above, the microcomputer 100A further includes the test ROM 130 in which a test program for testing at least the CPU 120 has been stored in the form of compressed code; and the test program decoding circuit 140 for decoding the stored test program. After it has been decompressed or decoded, the test program is fetched by the CPU 120 which, based upon the test program, is capable of testing itself based upon the test program. Further, the microcomputer 100A is equipped with a RAM 150 that is accessible via the address bus BA and data bus BD. The test program that has been stored in the test ROM 130 can be expanded in the RAM 150 or a test-result flag that is output from the CPU 120 can be stored in the RAM 150.

The microcomputer 100A further includes the first selector 160 for selecting information from the test ROM 130 and information from the test-program decoding circuit 140, and the second selector 170 for selecting the output of the first selector 160 and information from the flash memory 110. Whatever is selected by the second selector 170 can be loaded into the CPU 120. The microcomputer 100A further includes the test-mode decoding circuit 180 for decoding the test mode signal SM, which enters from the test mode terminal TM, thereby obtaining the internal test mode signal SMI. The control macro 111 of the flash memory 110, the CPU 120, the test ROM 130 and the first and second selectors 160, 170, respectively, are controlled or changed over by the internal test mode signal SMI.

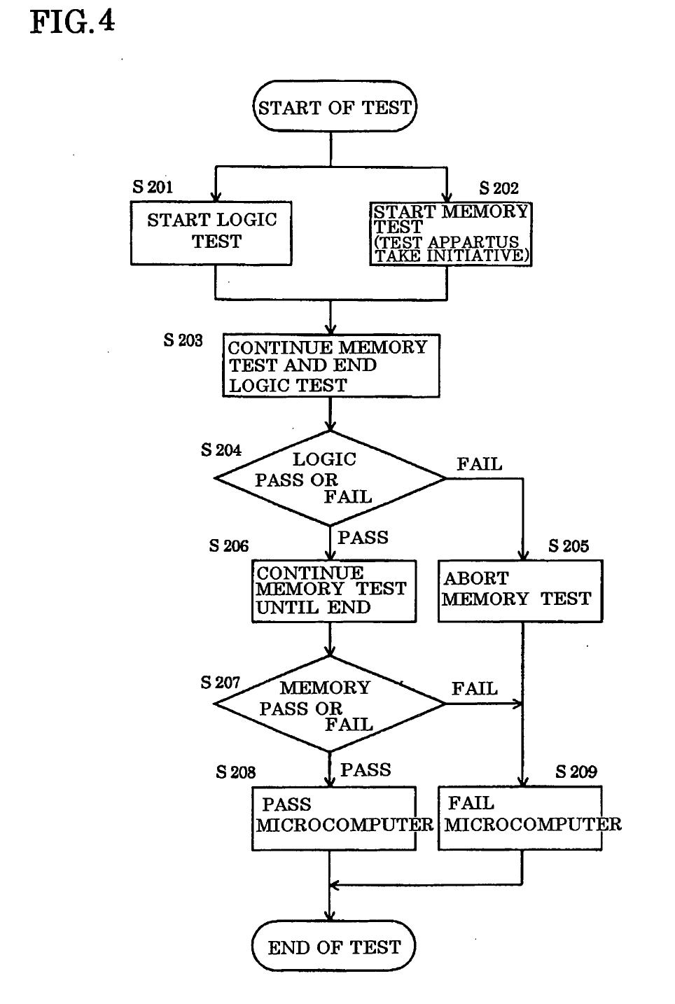

The operation for testing the microcomputer of the second embodiment set forth above will be described with reference to the flowchart of FIG. 4. When the test mode signal SM is input to the test mode terminal TM, the test-mode decoding circuit 180 generates the internal test mode signal SMI that conforms to the test mode, outputs the internal test mode signal SMI to the flash memory 110, CPU 120 and test ROM 130 and, at the same time, outputs the internal test mode signal SMI to the first and second selectors 160, 170, respectively. At this time, in response to the internal test mode signal SMI, the first selector 160 selects the output of the test-program decoding circuit 140 and the second selector 170 selects the output of the first selector 160. The test-program decoding circuit 140 decodes the test program that has been stored in the test ROM 130. Since the compressed test program stored in the test ROM 130 is decompressed and decoded at this time, a broad range of tests can be conducted by the CPU 120 even in a case where the test ROM 130 is of limited capacity.

Further, the CPU 120 selects the test program of the test ROM 130 by the first selector 160. Alternatively, the decoded test program is selected and the test program is expanded in the RAM 150, whereby the program is fetched by the CPU 120. Testing of the CPU 120 is executed based upon the test program fetched (S201). At the same time, the CPU 120 sends the required test pattern from the test apparatus 200 to the control macro 111 of the flash memory 110 via the test input terminal TIN, thereby controlling the control macro 111 and starting a test of the flash memory 110 (S202).

If testing of the CPU 120 ends first even though testing of the flash memory 110 is continuing (S203), the CPU 120 determines pass or fail and stores a pass flag or fail flag in the RAM 150 or internal register 112. If self-testing of the CPU 120 fails, then the CPU 120 controls the control macro 111 of the flash memory 110 and aborts testing of the flash memory 110 (S205). If the CPU 120 passes the self-test, then the CPU 120 continues the test of the flash memory 110 until the test is completed (S206). Next, the control macro 111 stores the flag, which indicates whether the result of testing is pass or fail, in the internal register 112 or in the RAM 150, the latter via the CPU 120. The CPU 120 thenceforth checks the flag that has been stored in the internal register 112 or RAM 150, determines whether the flash memory 110 has passed or failed, decides that the microcomputer 100A is a conforming article in case of pass (S208) and decides that it is defective in case of fail (S209).

By adopting this arrangement, testing of the flash memory 110 serving as the memory and testing of the CPU 120 serving as the logical circuit can be conducted simultaneously, just as in the first embodiment. In the testing of the flash memory 110, test time is longer than that for testing the CPU 120 because all of the memory cells are tested by repeating the test for each individual memory cell. Consequently, total test time for the present test can be held to the test time of the flash memory 110, which has the longer test time, and hence it is possible to shorten test time. In addition, it goes without saying that wasted test time can be eliminated.

Accordingly, with the microcomputer 100A of the second embodiment, it is unnecessary to provide switching circuits for changing over the externally applied memory test pattern and logic test pattern as time passes, as is required in the above-mentioned patent reference. This makes it possible to simplify the architecture of the microcomputer and to reduce its size. Further, according to the second embodiment, the CPU 120 takes the initiative in executing testing and in controlling testing based upon a check of flags. When testing is performed, therefore, it is possible to alleviate the burden on the side of the test apparatus 200. In addition, it is unnecessary to provide a large number of pins in order to test the memory of the microcomputer.

In the first and second embodiments described above, a flag indicating whether the result of testing a CPU or flash memory is pass or fail is stored in an internal register or in a RAM and the flag is checked by the CPU or by a control macro. However, it is also possible to check the flag from the external test apparatus after the test is completed, thereby determining whether the CPU or flash memory has passed or failed the test.

As many apparently widely different embodiments of the present invention can be made without departing from the spirit and scope thereof, it is to be understood that the invention is not limited to the specific embodiments thereof except as defined in the appended claims.

1. A microcomputer comprising:
a memory;
a logical circuit;
a test ROM storing a test program for testing at least said logical circuit; and
a recording device for storing, as a flag, a result of testing at least one of said memory and logical circuit.

2. The microcomputer according to claim 1, further comprising means for checking the flag, which has been stored in said recording device, after the end of testing of at least one of said memory and logical circuit.

3. The microcomputer according to claim 2, further comprising means for aborting a continuing test based upon result of checking the flag.

4. The microcomputer according to claim 1, wherein said means for checking the flag is a control macro for controlling said logical circuit or said memory.

5. The microcomputer according to claim 1, wherein said recording device comprises a RAM that expands the test program that has been stored in said test ROM.

6. The microcomputer according to claim 1, wherein said recording device comprises an internal register provided in said memory.

7. A method of testing a microcomputer having a memory and logical circuit, said method comprising the steps of:
testing the memory and, at the same time, testing the logical circuit based upon a test program that has been stored in a test ROM incorporated in the microcomputer;
storing a flag, which indicates a result of testing one of the memory and logical circuit, in a recording device; and
aborting testing of the other of the memory and logical circuit when test failure is confirmed based upon the flag.

8. The method according to claim 7, further comprising the steps of:
storing a flag indicating result of testing the logical circuit in the recording device; and
aborting testing of the memory when it is confirmed based upon the flag that the logical circuit is defective.

9. The method according to claim 8, wherein aborting of testing of the memory is performed under control by a control macro of the memory.

10. The method according to claim 8, wherein aborting of testing of the memory is performed under control by the logical circuit.

11. The method according to claim 7, wherein the logical circuit conducts testing upon fetching the test program, which has been stored in the test ROM, directly, or upon fetching the test program, which has been expanded in a RAM.
